(19) United States
(12) Patent Application Publication
(10) Pub. No.: US 2009/0289692 A1
(43) Pub. Date: Nov. 26, 2009

(54) Nagative voltage switch

(76) Inventor: Ting Huei Chen, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/232,021

(22) Filed: Sep. 10, 2008

(30) Foreign Application Priority Data
May 21, 2008 (TW) 97118692

(51) Int. Cl. H03K 17/687

(52) U.S. Cl. 327/434

(57) ABSTRACT

A negative voltage switch includes a switch unit, a voltage level converting circuit, and a discharge circuit. The switch unit has an input terminal for receiving a negative input voltage and an output terminal coupled to a load. The voltage level converting circuit receives a control signal and switches the switch unit to a first state or a second state according to the control signal. The switch circuit is switched to the first state if the level of the control signal is higher than a predetermined level and is switched to the second state if the level of the control signal is lower than the predetermined level, and the predetermined level is higher than the level of the negative input voltage.

### BACKGROUND OF THE INVENTION

1. Field of the Invention

The present invention relates to a negative voltage switch, and more particularly to a negative voltage switch having a discharge path.

2. Description of Related Art

In recent years, due to scientific and technological advance, various types of electronic products and their applications are rapidly developed. As we all know, a power supply device is one of the basic equipments required for the operation of the electronic products, and the quality of the power supply device substantially affects overall operation and performance of the electronic products.

In general, the design of a power supply device for an electronic product usually adopts a DC/DC converter for converting a voltage to meet the requirement for operation of a load, and a DC/DC buck converter is illustrated below.

With reference to FIG. 1, which shows a schematic circuit diagram of a conventional DC/DC buck converter, the DC/DC buck converter 9 includes an inductor L, a diode D, a capacitor C, and a power transistor Q, wherein operation of the power transistor Q is controlled by a gate voltage VG.

If the power transistor Q is turned on, the diode D is reversed-bias and the current produced by the input voltage VIN flows forward through the inductor L to charge the capacitor C and generates an output voltage VOUT supplied to a load R. Meanwhile, the current through the inductor L is increased for storing electric energy.

On the other hand, if the power transistor Q is turned off, the current through the inductor L continues, and thus the polarity of the inductor L is reversed to release the electric energy stored in the inductor L to charge the capacitor C through the diode D. In the meantime, the capacitor C keeps supplying the output voltage VOUT to the load R.

However, electronic products of different applications require different driving voltage levels. Therefore, there may be a difference between driving voltage levels of circuits of different stages, for example the reference voltage levels (grounding level) may be different. As a result, the positive driving voltage level of the previous stage may become a negative voltage level for the present stage. The power transistor Q of the above mentioned DC/DC converter can be operated successfully when a positive input voltage VIN is applied, however, it cannot be operated when a negative input voltage is applied.

### SUMMARY OF THE INVENTION

In view of the foregoing shortcomings of the prior art, the present invention provides a negative voltage switch, wherein a switch unit of the negative voltage switch can be turned on to supply a negative voltage to a load, or turned off to provide a discharge path to the load.

The primary objective of the present invention is to provide a negative voltage switch comprising a switch unit, a voltage level converting circuit, and a discharge circuit. The switch unit has an input terminal, an output terminal, and a control terminal, wherein the input terminal is utilized for receiving a negative input voltage, and the output terminal is utilized for coupling a load. The voltage level converting circuit receives a control signal and switches the switch unit to a first state or a second state according to the control signal. In detail, if the level of the control signal is higher than a predetermined level, the switch unit is switched to the first state, and if the level of the control signal is lower than the predetermined level, the switch unit is switched to the second state, wherein the predetermined level is higher than the level of the negative input voltage. The discharge circuit is coupled to the output terminal of the switch unit and a reference terminal for receiving the control signal. If the switch unit is turned off, the discharge circuit electrically connects the load with the reference terminal. Therefore, the negative voltage switch of the present invention can supply a negative voltage to the load and provide a discharge path to the load.

In addition to the general description above, preferred embodiments together with related drawings are provided for illustrating the technical characteristics of the present invention, and other objectives and advantages of the present invention will be described as follows.

### BRIEF DESCRIPTION OF THE DRAWINGS

FIG. 1 is a schematic circuit diagram of a conventional DC-to-DC buck converter;

FIG. 2 is a block diagram of a negative voltage switch in accordance with the present invention;

FIG. 3 is a circuit diagram of a negative voltage switch in accordance with a first preferred embodiment of the present invention;

FIG. 4 is a circuit diagram of a negative voltage switch in accordance with a second preferred embodiment of the present invention;

FIG. 5 is a circuit diagram of a negative voltage switch in accordance with a third preferred embodiment of the present invention; and

FIG. 6 is a circuit diagram of a negative voltage switch in accordance with a fourth preferred embodiment of the present invention.

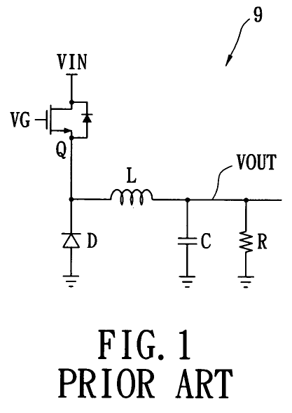

### DETAILED DESCRIPTION OF PREFERRED EMBODIMENTS

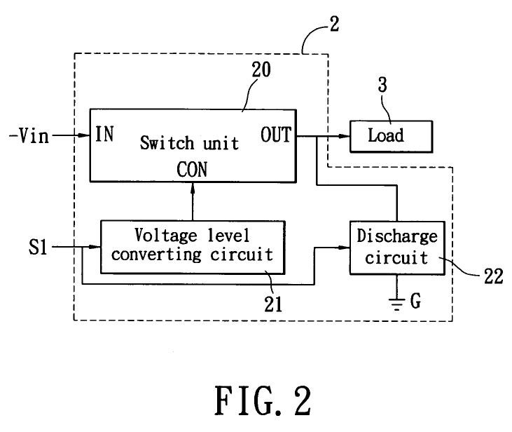

With reference to FIG. 2, which shows a block diagram of a negative voltage switch in accordance with the present invention, the negative voltage switch 2 comprises a switch unit 20, a voltage level converting circuit 21, and a discharge circuit 22. The switch unit 20 has an input terminal IN, an output terminal OUT, and a control terminal CON. The input terminal IN of the switch unit 20 is utilized to receive a negative input voltage −Vin, and the output terminal OUT is coupled to a load 3. In addition, the voltage level converting circuit 21 receives a control signal S1, and controls the operation of the switch unit 20 through the control terminal CON of the switch unit 20. The switch unit 20 is switched between a first state and a second state according to the control signal S1. In detail, if the level of the control signal S1 is higher than a predetermined level, the switch unit 20 will be switched to the first state, and if the level of the control signal S1 is lower than the predetermined level, the switch unit 20 will be switched to the second state, wherein the predetermined level is higher than the level of the negative input voltage −Vin.

With reference to FIG. 2 again, the discharge circuit 22 of the negative voltage switch 2 is coupled to the output terminal OUT of the switch unit 20 and to a reference terminal G and receives the control signal S1. The discharge circuit 22 electrically connects the load 3 with the reference terminal G when the switch unit 20 is turned off for providing a discharging path to the load 3.

With reference to FIG. 3, which shows a schematic circuit diagram of a negative voltage switch in accordance with a first preferred embodiment of the present invention, the negative voltage switch 2a comprises a first transistor Q1, a second transistor Q2, and a discharge circuit 22. The discharge circuit 22 comprises a third transistor Q3 and a fourth transistor Q4. The first transistor Q1 is corresponding to the switch unit 20 in FIG. 2, and the second transistor Q2 is corresponding to the voltage level converting circuit 21 in FIG. 2.

In the negative voltage switch 2a, a first source/drain of the first transistor Q1 is utilized for receiving a negative input voltage −Vin, and a second source/drain of the first transistor Q1 is coupled to a load (not shown in the figure) for supplying a negative output voltage −Vout. That is, the input terminal IN of the switch unit 20 is corresponding to the first source/drain of the first transistor Q1, the output terminal OUT of the switch unit 20 is corresponding to the second source/drain of the first transistor Q1, and the control terminal CON of the switch unit 20 is corresponding to the gate of the first transistor Q1. In the meantime, a third source/drain of the second transistor Q2 is coupled to a gate of the first transistor Q1, a fourth source/drain of the second transistor Q2 is utilized to receive a control signal S1, and a gate of the second transistor Q2 is coupled to a reference terminal G. In the present embodiment, the first transistor Q1 is an n-type MOSFET, and the second transistor Q2 is a p-type MOSFET. With reference to FIG. 3, the negative voltage switch 2a further comprises a hysteresis comparator 202 and a first resistor R1, wherein the hysteresis comparator 202 is coupled to the fourth source/drain of the second transistor Q2 for converting an enable signal EN into the control signal S1 and providing the control signal S1 to the fourth source/drain of the second transistor Q2. The first resistor R1 is coupled between the first source/drain and the gate of the first transistor Q1 for preventing the first transistor Q1 from wrongly operated because the gate of the first transistor Q1 is floated. In addition, a second resistor R2 can be interposed between the gate of the first transistor Q1 and the third source/drain of the second transistor Q2. The first resistor R1 and the second resistor R2 constitutes a voltage divider in order to prevent the first transistor Q1 from being burned out or damaged by an excessive voltage drop crossing the first resistor R1.

As to the operation of the negative voltage switch 2a, if the enable signal EN is high, the control signal S1 will be high to turn on the second transistor Q2. Meanwhile, the conducted second transistor Q2 transmits the high-level control signal S1 to the gate of the first transistor Q1 to turn on of the first transistor Q1. Thereby, the conducted first transistor Q1 converts the negative input voltage −Vin into the negative output voltage −Vout and outputs the negative output voltage −Vout to the load. On the other hand, if the enable signal EN is low, the control signal S1 will be low to turn off the second transistor Q2. Meanwhile, because the gate and the first source/drain of the first transistor Q1 have the same electric potential, the first transistor Q1 is turned off to stop outputting the negative output voltage −Vout.

With reference to FIG. 3 again, according to the design of the discharge circuit 22, there may be an inverter 204 coupled between a hysteresis comparator 202 and the gate of the third transistor Q3 in the discharge circuit 22 of the negative voltage switch 2a. The inverter 204 has an input terminal for receiving the control signal S1 and has an output terminal for outputting an inverted control signal S2. In addition, a gate of the third transistor Q3 is coupled to the output terminal of the inverter 204, a fifth source/drain of the third transistor Q3 is coupled to a voltage source Vcc, and a sixth source/drain of the third transistor Q3 is coupled to the reference terminal G. A seventh source/drain of the fourth transistor Q4 is coupled to the second source/drain of the first transistor Q1 and the load, an eighth source/drain of the fourth transistor Q4 is coupled to the reference terminal G, and a gate of the fourth transistor Q4 is coupled to the fifth source/drain of the third transistor. In the present embodiment, the third transistor Q3 is an n-type MOSFET, and the fourth transistor Q4 is a p-type junction field effect transistor (JFET).

With reference to FIG. 3, as to the operation of the negative voltage switch 2a, if the enable signal EN is high, the control signal S1 will be high and the inverted control signal S2 will be low. The low-level inverted control signal S2 turns off the third transistor Q3 to have the voltage level of the voltage source Vcc supplied to the gate of the fourth transistor Q4 to turn off the fourth transistor Q4. On the other hand, if the enable signal EN is low, the control signal S1 will be low and the inverted control signal S2 will be high to turn on the third transistor Q3 for connecting the gate of the fourth transistor Q4 to the reference terminal G to turn on the fourth transistor Q4. The conducted fourth transistor Q4 provides a discharge path for the load.

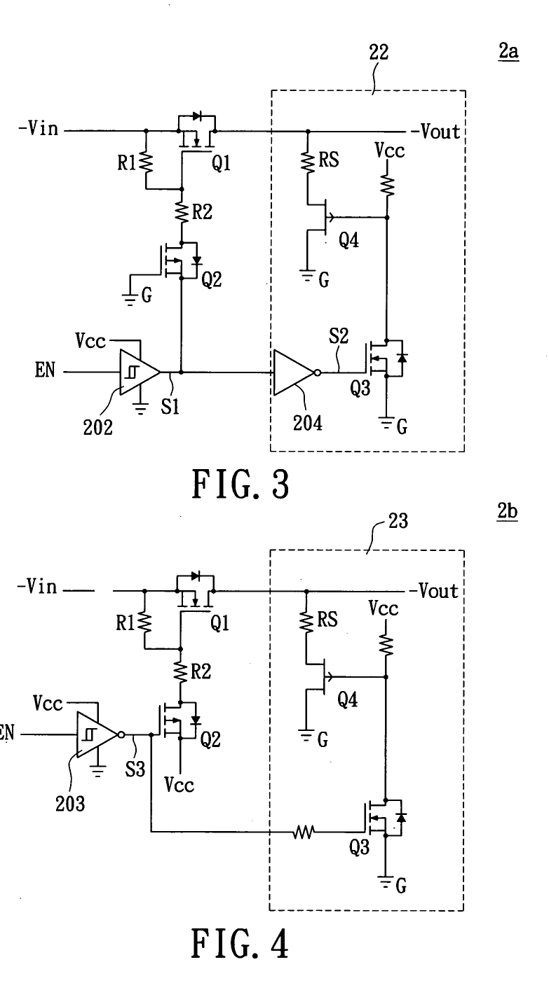

FIG. 4 shows a schematic circuit diagram of a negative voltage switch in accordance with a second preferred embodiment of the present invention. Referring to FIGS. 3 and 4, the operation principle and the function of the negative voltage switch 2b of the second preferred embodiment are the same as those of the negative voltage switch 2a of the first preferred embodiment. The major difference between the two embodiments lies in that the negative voltage switch 2b of the second preferred embodiment uses a inverted hysteresis comparator 203 to substitute the hysteresis comparator 202 of the first preferred embodiment, and the discharge circuit 23 of the second preferred embodiment saves the inverter 204 of the discharge circuit 22 of the first preferred embodiment. In the second preferred embodiment, an output terminal of the inverted hysteresis comparator 203 is coupled to the gate of the second transistor Q2 and the gate of the third transistor Q3, an input terminal of the inverted hysteresis comparator 203 is utilized for receiving an enable signal EN and converting the enable signal EN into a control signal S3, and the control signal S3 is transmitted to the gate of the second transistor Q2 and the gate of the third transistor Q3. In addition, the fourth source/drain of the second transistor Q2 is coupled to a voltage source Vcc.

With reference to FIG. 4 again, as to the operation of the negative voltage switch 2b, if the enable signal EN is high, the control signal S3 will be low to turn on the second transistor Q2 to have the high-level voltage of the voltage source Vcc supplied to the gate of the first transistor Q1 to turn on the first transistor Q1. The conducted first transistor Q1 will convert the negative input voltage −Vin into the negative output voltage −Vout and output the negative output voltage −Vout to the load. In the meantime, the low-level control signal S3 turns off the third transistor Q3 to have the voltage level of the voltage source Vcc supplied to the gate of the fourth transistor Q4 to turn off the fourth transistor Q4.

On the other hand, if the enable signal EN is low, the control signal S3 will be high to turn off the second transistor Q2. Meanwhile, because the gate and the first source/drain of the first transistor Q1 have the same voltage level, the first transistor Q1 would be turned off to stop outputting the negative output voltage −Vout. In the meantime, the high-level control signal S3 turns on the third transistor Q3 to electrically connect the gate of the fourth transistor Q4 with the reference terminal G so as to turn on the fourth transistor Q4. The conducted fourth transistor Q4 provides a discharge path for the load.

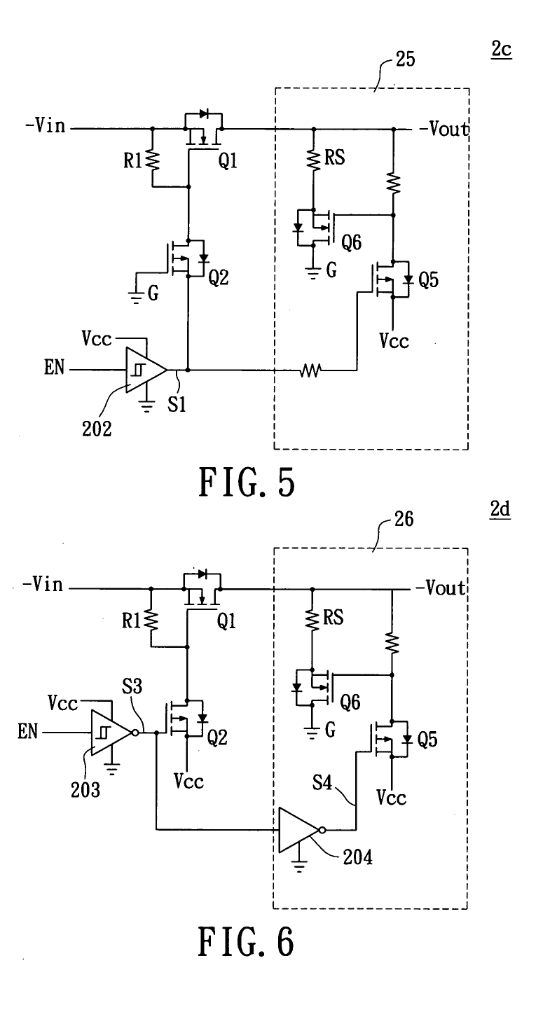

FIG. 5 shows a schematic circuit diagram of a negative voltage switch in accordance with a third preferred embodiment of the present invention. Referring to FIGS. 3 and 5, the operation principle and function of the negative voltage switch 2c of the third preferred embodiment are the same as those of the negative voltage switch 2a of the first preferred embodiment. The major difference between the two embodiments lies in that the discharge circuit 25 of the third preferred embodiment uses a p-type MOSFET Q5 to substitute the n-type MOSFET Q3 of the discharge circuit 22 of the first preferred embodiment and uses an n-type MOSFET Q6 to substitute the p-type JFET Q4 of the discharge circuit 22 of the first preferred embodiment. In addition, the discharge circuit 25 of the third preferred embodiment saves the inverter 204 in the discharge circuit 22 of the first preferred embodiment.

The gate of the p-type MOSFET Q5 receives the control signal S1 from the hysteresis comparator 202, the fifth source/drain of the p-type MOSFET Q5 is coupled to the second source/drain of the first transistor Q1, and the sixth source/drain of the p-type MOSFET Q5 is coupled to the voltage source Vcc. The seventh source/drain of the n-type MOSFET Q6 is coupled to the second source/drain of the first transistor Q1, the eighth source/drain of the n-type MOSFET Q6 is coupled to the reference terminal G, and the gate of the n-type MOSFET Q6 is coupled to the fifth source/drain of the p-type MOSFET Q5.

With reference to FIG. 5, as to the operation of the negative voltage switch 2c, if the enable signal EN is high, the control signal S1 will be high to turn off the p-type MOSFET Q5. Meanwhile, the negative output voltage −Vout is supplied to the gate of the n-type MOSFET Q6 to turn off the n-type MOSFET Q6. On the other hand, if the enable signal EN is low, the control signal S1 will be low to turn on the p-type MOSFET Q5. The conducted p-type MOSFET Q5 electrically connect the gate of the n-type MOSFET Q6 with the voltage source Vcc to turn on the n-type MOSFET Q6. The conducted n-type MOSFET Q6 provides a discharge path for the load.

FIG. 6 shows a schematic circuit diagram of a negative voltage switch in accordance with a fourth preferred embodiment of the present invention. Referring to FIGS. 4 and 6, the operation principle and function of the negative voltage switch 2d of the fourth preferred embodiment are the same as those of the negative voltage switch 2b of the second preferred embodiment. The major difference between the two embodiments lies in that the discharge circuit 26 of the fourth preferred embodiment uses a p-type MOSFET Q5 to substitute the n-type MOSFET Q3 of the discharge circuit 23 of the second preferred embodiment and an n-type MOSFET Q6 to substitute the p-type JFET Q4 of the discharge circuit 23 of the second preferred embodiment. In addition, the discharge circuit 26 of the fourth embodiment has an inverter 204.

An input terminal of the inverter 204 of the discharge circuit 26 is coupled to the output terminal of the inverted hysteresis comparator 203, and an output terminal of the inverter 204 is coupled to the gate of the p-type MOSFET Q5. Therefore, the inverter 204 receives the control signal S3 from the inverted hysteresis comparator 203 and outputs an inverted control signal S4 to the p-type MOSFET Q5. The fifth source/drain of the p-type MOSFET Q5 is coupled to the second source/drain of the first transistor Q1, and the sixth source/drain of the p-type MOSFET Q5 is coupled to the voltage source Vcc. In the meantime, the seventh source/drain of the n-type MOSFET Q6 is coupled to the second source/drain of the first transistor Q1, the eighth source/drain of the n-type MOSFET Q6 is coupled to the reference terminal G, and the gate of the n-type MOSFET Q6 is coupled to the fifth source/drain of the p-type MOSFET Q5.

With reference to FIG. 6, as to the operation of the negative voltage switch 2c, if the enable signal EN is high, the control signal S3 will be low, and the inverted control signal S4 will be high to turn off the p-type MOSFET Q5. Meanwhile, the negative output voltage −Vout is supplied to the gate of the n-type MOSFET Q6 to turn off the n-type MOSFET Q6. On the other hand, if the enable signal EN is low, the control signal S3 will be high and the inverted control signal S4 will be low to turn on the p-type MOSFET Q5. The conducted p-type MOSFET Q5 electrically connects the gate of the n-type MOSFET Q6 with the voltage source Vcc so as to turn on the n-type MOSFET Q6. The conducted n-type MOSFET Q6 provides a discharge path for the load.

In summation of the description above, the negative voltage switch in accordance with the present invention converts the negative input voltage and supplies the negative output voltage to a load as the switch unit is turned on and provides a discharge path to the load as the switch unit is turned off.

Although the present invention has been described with reference to the preferred embodiments thereof, it will be understood that the present invention is not limited to the details thereof. Various substitutions and modifications have been suggested in the foregoing description, and others will occur to those of ordinary skill in the art. Therefore, all such substitutions and modifications are intended to be embraced within the scope of the present invention as defined in the appended claims.

What is claimed is:

1. A negative voltage switch, comprising:
a switch unit, having an input terminal, an output terminal, and a control terminal, the input terminal receiving a negative input voltage, and the output terminal being coupled to a load;
a voltage level converting circuit, receiving a control signal and switching the switch unit to a first state or a second state according to the control signal; and
a discharge circuit, coupled to the output terminal of the switch unit and a reference terminal, receiving the control signal, and electrically connecting the load with the reference terminal as the switch unit is turned off;
wherein, the switch unit is switched to the first state as the level of the control signal is higher than a predetermined level, the switch unit is switched to the second state as the level of the control signal is lower than the predetermined level, and the predetermined level is higher than the level of the negative input voltage.

2. The negative voltage switch of claim 1, wherein the switch unit is a first transistor, the input terminal of the switch unit is a first source/drain of the first transistor, the output terminal of the switch unit is a second source/drain of the first transistor, and the control terminal of the switch unit is a gate of the first transistor.

3. The negative voltage switch of claim 1, wherein the voltage level converting circuit comprises a second transistor (Q2), having a third source/drain, a fourth source/drain, and a gate, the third source/drain being coupled to a control terminal of the switch unit, the fourth source/drain receiving the control signal, and the gate of the second transistor (Q2) being coupled to a reference terminal.

4. The negative voltage switch of claim 3, wherein the discharge circuit further comprises:
a third transistor (Q3), having a fifth source/drain, a sixth source/drain, and a gate, the gate of the third transistor (Q3) receiving the control signal, the fifth source/drain being coupled to a voltage source, and the sixth source/drain being coupled to the reference terminal; and
a fourth transistor (Q4), having a seventh source/drain, a eighth source/drain, and a gate, the seventh source/drain being coupled to the output terminal of the switch unit, the eighth source/drain being coupled to the reference terminal, and the gate of the fourth transistor (Q4) being coupled to the fifth source/drain of the third transistor (Q3).

5. The negative voltage switch of claim 3, wherein the discharge circuit further comprises:
a fifth transistor (Q5), having a fifth source/drain, a sixth source/drain, and a gate, the gate of the fifth transistor (Q5) receiving the control signal, the fifth source/drain being coupled to the output terminal of the switch unit, and the sixth source/drain being coupled to a voltage source; and
a sixth transistor (Q6), having a seventh source/drain, a eighth source/drain, and a gate, the seventh source/drain being coupled to the output terminal of the switch unit, the eighth source/drain being coupled to the reference terminal, and the gate of the sixth transistor (Q6) being coupled to the fifth source/drain of the fifth transistor (Q5).

6. The negative voltage switch of claim 3, wherein the voltage level converting circuit further comprises a first resistor coupled between the input terminal and the control terminal of the switch unit.

7. The negative voltage switch of claim 6, wherein the voltage level converting circuit further comprises a second resistor coupled between the control terminal of the switch unit and the third source/drain of the second transistor (Q2).

8. The negative voltage switch of claim 6, wherein the discharge circuit comprises an inverter, having an input terminal and an output terminal, the input terminal of the inverter receiving the control signal, and the output terminal of the inverter outputting an inverted control signal.

9. The negative voltage switch of claim 8, wherein the discharge circuit further comprises:
a third transistor (Q3), having a fifth source/drain, a sixth source/drain, and a gate, the gate of the third transistor (Q3) being coupled to the output terminal of the inverter, the fifth source/drain being coupled to a voltage source, and the sixth source/drain being coupled to the reference terminal; and
a fourth transistor (Q4), having a seventh source/drain, a eighth source/drain, and a gate, the seventh source/drain being coupled to the output terminal of the switch unit, the eighth source/drain being coupled to the reference terminal, and the gate of the fourth transistor (Q4) being coupled to the fifth source/drain of the third transistor (Q3).

10. The negative voltage switch of claim 8, wherein the discharge circuit further comprises:
a third transistor (Q3), having a fifth source/drain, a sixth source/drain, and a gate, the gate of the third transistor (Q3) being coupled to the output terminal of the inverter, the fifth source/drain being coupled to the output terminal of the switch unit, and the sixth source/drain being coupled to a voltage source; and
a fourth transistor (Q4), having a seventh source/drain, a eighth source/drain, and a gate, the seventh source/drain being coupled to the output terminal of the switch unit, the eighth source/drain being coupled to the reference terminal, and the gate of the fourth transistor (Q4) being coupled to the fifth source/drain of the third transistor (Q3).

11. The negative voltage switch of claim 3, further comprising a comparator, for receiving an enable signal and converting the enable signal into the control signal.

12. The negative voltage switch of claim 1, wherein the voltage level converting circuit comprises a second transistor (Q2) having a third source/drain, a fourth source/drain, and a gate, the third source/drain is coupled to the control terminal of the switch unit, the fourth source/drain is coupled to a voltage source, and the gate of the second transistor (Q2) receiving the control signal.

13. The negative voltage switch of claim 12, wherein the discharge circuit further comprises:
a third transistor (Q3), having a fifth source/drain, a sixth source/drain, and a gate, the gate of the third transistor (Q3) receiving the control signal, the fifth source/drain being coupled to a voltage source, and the sixth source/drain being coupled to the reference terminal; and
a fourth transistor (Q4), having a seventh source/drain, a eighth source/drain, and a gate, the seventh source/drain being coupled to the output terminal of the switch unit, the eighth source/drain being coupled to the reference terminal, and the gate of the fourth transistor (Q4) being coupled to the fifth source/drain of the third transistor (Q3).

14. The negative voltage switch of claim 12, wherein the discharge circuit further comprises:
a fifth transistor (Q5), having a fifth source/drain, a sixth source/drain, and a gate, the gate of the fifth transistor (Q5) receiving the control signal, the fifth source/drain being coupled to the output terminal of the switch unit, and the sixth source/drain being coupled to a voltage source; and
a sixth transistor (Q6), having a seventh source/drain, a eighth source/drain, and a gate, the seventh source/drain being coupled to the output terminal of the switch unit, the eighth source/drain being coupled to the reference terminal, and the gate of the sixth transistor (Q6) being coupled to the fifth source/drain of the fifth transistor (Q5).

15. The negative voltage switch of claim 12, wherein the voltage level converting circuit further comprises a first resistor coupled between the input terminal of the switch unit and the control terminal.

16. The negative voltage switch of claim 15, wherein the voltage level converting circuit further comprises a second resistor coupled between the control terminal of the switch unit and the third source/drain of the second transistor (Q2).

17. The negative voltage switch of claim 15, wherein the discharge circuit comprises an inverter, having an input terminal for receiving the control signal and an output terminal for outputting an inverted control signal.

18. The negative voltage switch of claim 17, wherein the discharge circuit further comprises:
a third transistor (Q3), having a fifth source/drain, a sixth source/drain, and a gate, the gate of the third transistor (Q3) being coupled to the output terminal of the inverter, the fifth source/drain being coupled to a voltage source, and the sixth source/drain being coupled to the reference terminal; and
a fourth transistor (Q4), having a seventh source/drain, a eighth source/drain, and a gate, the seventh source/drain being coupled to the output terminal of the switch unit, the eighth source/drain being coupled to the reference terminal, and the gate of the fourth transistor (Q4) being coupled to the fifth source/drain of the third transistor (Q3).

19. The negative voltage switch of claim 17, wherein the discharge circuit further comprises:
a fifth transistor (Q5), having a fifth source/drain, a sixth source/drain, and a gate, the gate of the fifth transistor (Q5) being coupled to the output terminal of the inverter, the fifth source/drain being coupled to the output terminal of the switch unit, and the sixth source/drain being coupled to a voltage source; and
a sixth transistor (Q6), having a seventh source/drain, a eighth source/drain, and a gate, the seventh source/drain being coupled to the output terminal of the switch unit, the eighth source/drain being coupled to the reference terminal, and the gate of the sixth transistor (Q6) being coupled to the fifth source/drain of the fifth transistor (Q5).

20. The negative voltage switch of claim 12, further comprising a comparator, for receiving an enable signal and converting the enable signal into the control signal.
